(19) United States
(12) Patent Application Publication
(10) Pub. No.: US 2023/0095829 A1
(43) Pub. Date: Mar. 30, 2023

(54) ORGANIC PHOTOELECTRIC CONVERSION DEVICE AND IMAGE SENSOR INCLUDING THE SAME

(71) Applicant: SAMSUNG ELECTRONICS CO., LTD., Suwon-si (KR)

(72) Inventors: Ki-Ryong LEE, Seoul (KR); Joon Hak OH, Seoul (KR); Inho SONG, Seoul (KR); Jaeyong AHN, Seoul (KR); Junwon HAN, Seoul (KR)

(73) Assignee: Seoul National University R&DB Foundation, Seoul (KR)

(21) Appl. No.: 17/700,841

(22) Filed: Mar. 22, 2022

(30) Foreign Application Priority Data
Sep. 3, 2021 (KR) 10-2021-0117941

(51) Int. Cl. H01L 51/00; H01L 51/42; H01L 51/52

(52) U.S. Cl. CPC H01L 51/0083; H01L 51/42; H01L 51/0092; H01L 51/5203; H01L 51/0036

(57) ABSTRACT

An organic photoelectric conversion device and an image sensor, the organic photoelectric conversion device including an upper electrode; a lower electrode; and an active layer between the upper electrode and the lower electrode, wherein the active layer includes bis-(4-dimethylaminodithiobenzyl)-Ni(II) (BDN) and [6,6]-Phenyl-C71-butyric acid methyl ester (PC70BM).

### CROSS-REFERENCE TO RELATED APPLICATION

This application is based on and claims priority under 35 U.S.C. § 119 to Korean Patent Application No. 10-2021-0117941, filed on Sep. 3, 2021, in the Korean Intellectual Property Office, the disclosure of which is incorporated by reference herein in its entirety.

### BACKGROUND

### 1. Field

Embodiments relate to an organic photoelectric conversion device and an image sensor including the same.

### 2. Description of the Related Art

Short wave infrared (SWIR) rays have a wavelength in a range of about 1 μm to about 3 μm. An image sensor including a SWIR photoelectric conversion device may be used for, e.g., environmental contamination, surveillance, bioimages, medical care, agriculture, food, or vehicles.

### SUMMARY

The embodiments may be realized by providing an organic photoelectric conversion device including an upper electrode; a lower electrode; and an active layer between the upper electrode and the lower electrode, wherein the active layer includes bis-(4-dimethylaminodithiobenzyl)-Ni(II) (BDN) and [6,6]-Phenyl-C71-butyric acid methyl ester (PC70BM).

The embodiments may be realized by providing an organic photoelectric conversion device including an upper electrode; a lower electrode; and an active layer between the upper electrode and the lower electrode, wherein the active layer includes a first organic material and a second organic material, the first organic material and the second organic material form a charge transfer complex, and a light absorption spectrum of the charge transfer complex has a peak at a wavelength of 1.5 μm or more.

The embodiments may be realized by providing an image sensor including the organic photoelectric conversion device according to an embodiment.

The embodiments may be realized by providing an image sensor including a semiconductor substrate; a charge storage in the semiconductor substrate; an insulating layer on the semiconductor substrate; an organic photoelectric conversion device on the insulating layer; and a wiring connecting between the organic photoelectric conversion device and the charge storage, wherein the organic photoelectric conversion device includes a lower electrode connected to the wiring; an active layer on the lower electrode; and an upper electrode on the active layer, the active layer includes a first organic material and a second organic material, the first organic material and the second organic material form a charge transfer complex, and a light absorption spectrum of the charge transfer complex has a peak at a wavelength of 1.5 μm or more.

### BRIEF DESCRIPTION OF THE DRAWINGS

Features will be apparent to those of skill in the art by describing in detail exemplary embodiments with reference to the attached drawings in which:

FIG. 1 is a cross-sectional view of an organic photoelectric conversion device according to an embodiment;

FIG. 2 is a cross-sectional view of an organic photoelectric conversion device according to an embodiment;

FIG. 3 is a chemical structure of bis-(4-dimethylaminodithiobenzyl)-Ni(II) (BDN);

FIG. 4 is a chemical structure of [6,6]-Phenyl-C71-butyric acid methyl ester (PC70BM);

FIG. 5 is a chemical structure of poly-3-hexylthiophene (P3HT);

FIG. 6 is a light absorption spectrum of BDN;

FIG. 7 is an energy level calculation result of BDN;

FIG. 8 is a light absorption spectrum of a film in which BDN and PC70BM were mixed;

FIG. 9 is a voltage-current graph of a First Example for sunlight;

FIG. 10 is a voltage-current graph of the First Example for light of about 1300 nm;

FIG. 11 is a time-current graph of the First Example;

FIG. 12 is an optical microscopy image of an active layer of the First Example;

FIG. 13 is an atomic force microscopy (AFM) image of the active layer of the First Example;

FIG. 14 is a cross-sectional profile of the active layer of the First Example, which is measured using AFM;

FIG. 15 is a time-current graph of a Second Example;

FIG. 16 is an AFM image of an active layer of the Second Example;

FIGS. 17A and 17B are cross-sectional profiles of the active layer of the Second Example, which is measured using AFM;

FIG. 18 is a cross-sectional view of an image sensor according to an embodiment; and

FIG. 19 is a cross-sectional view of an image sensor according to an embodiment.

### DETAILED DESCRIPTION

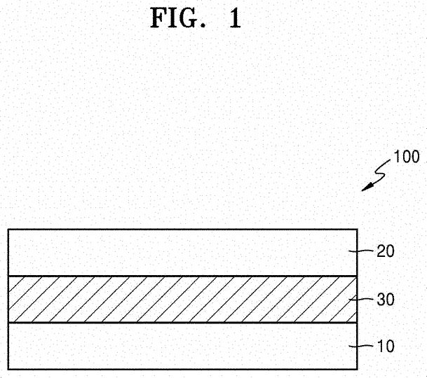

FIG. 1 is a cross-sectional view of an organic photoelectric conversion device 100 according to an embodiment.

Referring to FIG. 1, the organic photoelectric conversion device 100 may include a lower electrode 10, an upper electrode 20, and an active layer 30 between the lower electrode 10 and the upper electrode 20. In an implementation, the organic photoelectric conversion device 100 may include the lower electrode 10, the active layer 30, and the upper electrode 20 stacked in this stated order.

At least one of the lower electrode 10 and the upper electrode 20 may be a transparent electrode which transmits short wave infrared (SWIR) light therethrough. The lower electrode 10 and the upper electrode 20 may include, e.g., an indium tin oxide (ITO), an indium zinc oxide (IZO), an aluminum doped zinc oxide (AZO), a fluorine doped tin oxide (FTO), a tin oxide (SnO₂), a titanium oxide (TiO₂), a zinc oxide (ZnO), calcium (Ca), gold (Ag), silver (Ag), aluminum (Al), titanium (Ti), doped polysilicon graphene, a carbon nanotube (CNT), or a combination thereof. As used herein, the term “or” is not an exclusive term, e.g., “A or B” would include A, B, or A and B.

The active layer 30 may include a plurality of organic materials. The plurality of organic materials may include a light absorption material. In an implementation, the light absorption material may include, e.g., bis-(4-dimethylaminodithiobenzyl)-Ni(II) (BDN). BDN may be represented by Chemical Formula 1a.

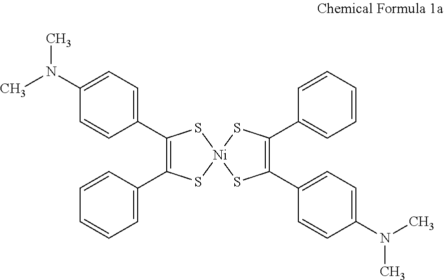

Chemical Formula, the light absorption material may be represented by, e.g., Chemical Formula 1b.

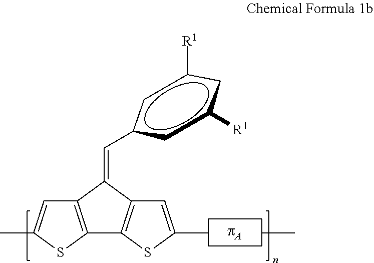

In Chemical Formula 1b, each R¹ may independently be or include, e.g., an alkyl group (e.g., a C1 to C30 alkyl group) and n is a natural number between 1 to 10000. π_{A} may be, e.g., a group represented by Chemical Formula 2a, Chemical Formula 2b, or Chemical Formula 2c. As used herein, “ [symbol] ” is a bonding location.

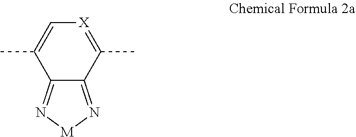

In Chemical Formula 2a, M may be, e.g., sulfur (S) or selenium (Se), and X may be, e.g., CH or nitrogen (N).

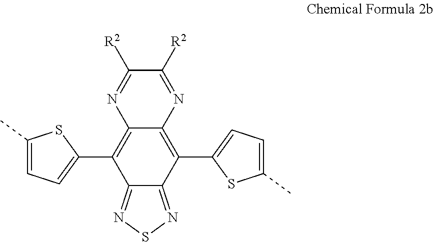

In Chemical Formula 2b, each R² may independently be or include, e.g., an alkyl group (e.g., a C1 to C30 alkyl group).

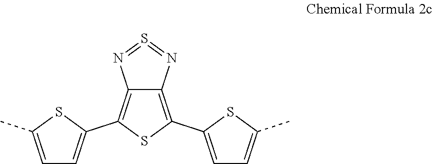

In an implementation, the light absorption material may be represented by Chemical Formula 1c.

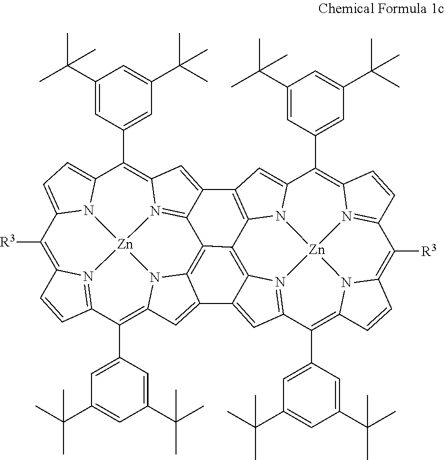

In Chemical Formula 1c, each R³ may independently be, e.g., a group represented by Chemical Formula 3a, Chemical Formula 3b, or Chemical Formula 3c.

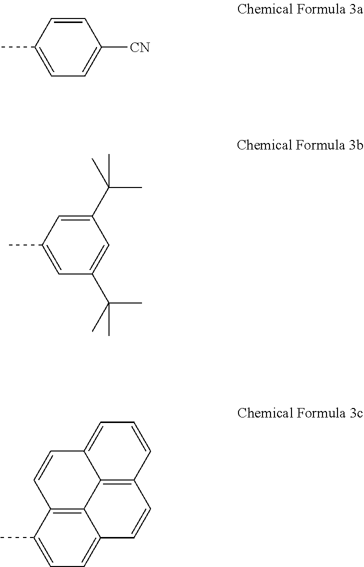

In an implementation, the light absorption material may be, e.g., represented by Chemical Formula 1d.

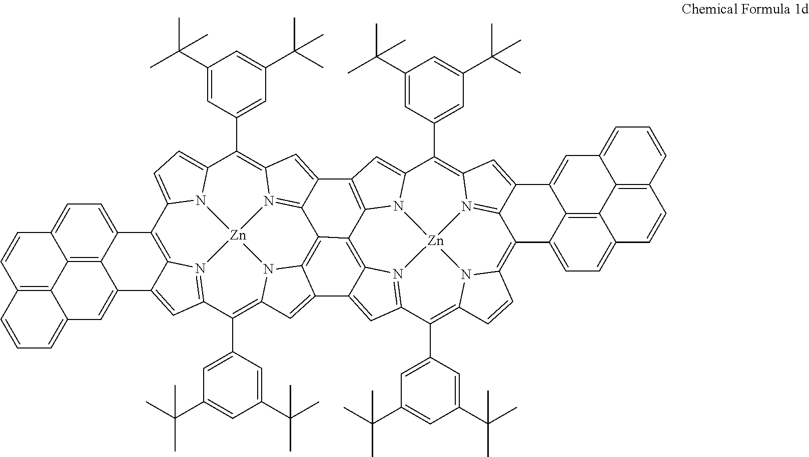

In an implementation, the active layer 30 may further include, e.g., a donor material or an acceptor material.

The donor material may include, e.g., poly-3-hexylthiophene (P3HT), poly[2-methoxy-5-(3,7-dimethyoctyoxyl)-1,4-phenylenevinylene] (MDMO-PPV), poly[[4,8-bis[(2-ethylhexyl)oxy]benzo[1,2-b:4,5-b′]dithiophene-2,6-diyl][3-fluoro-2-[(2-ethylhexyl)carbonyl]thieno[3,4-b]thiophenediyl]] (PTB7), poly[2,6-(4,4-bis-(2-ethylhexyl)-4H-cyclopenta [2,1-b;3,4-b]dithiophene)-alt-4,7(2,1,3-benzothiadiazole)] (PCPDTBT), poly[N-9′-heptadecanyl-2,7-carbazole-alt-5,5-(4′,7′-di-2-thienyl-2′,1′,3′-benzothiadiazole)] (PCDTBT), or poly{2,2′-(2,5-bis(2-octyldodecyl)-3,6-dioxo-2,3,5,6-tetrahydropyrrolo[3,4-c]pyrrole-1,4-diyl)dithieno[3,2-b]thiophene-5,5′-diyl-alt-thiophen-2,5-diyl} (DPPTT-T).

P3HT may be represented by Chemical Formula 4a.

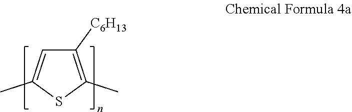

MDMO-PPV may be represented by Chemical Formula 4b.

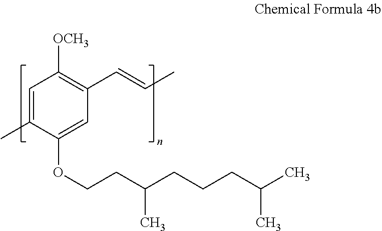

PTB7 may be represented by Chemical Formula 4c.

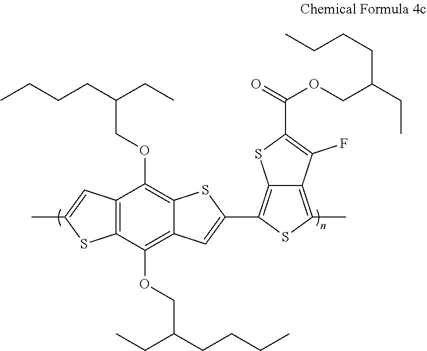

PCPDTBT may be represented by Chemical Formula 4d.

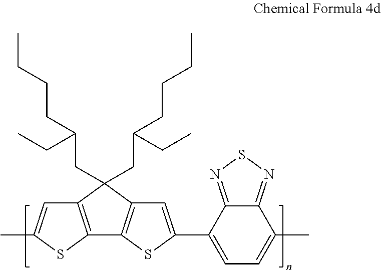

PCDTBT may be represented by Chemical Formula 4e.

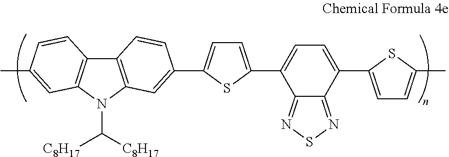

DPPTT-T may be represented by Chemical Formula 4f

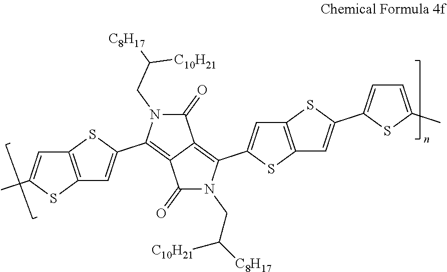

The acceptor material may include, e.g., PC70BM, [6,6]-phenyl-C61-butyric acid methyl ester (PC60BM), bis(1-[3-(methoxycarbonyl)propyl]-1-phenyl)-[6,6]C62 (bis-PCBM), poly {[N,N-bis(2-octyldodecyl)-naphthalene-1,4,5,8-bis(dicarboximide)-2,6-diyl]-alt-5,5-(2,29-bisthiophene)} (N2200), perylene diimide (PDI), or naphthalene diimide (NDI).

PC70BM may be represented by Chemical Formula 5a.

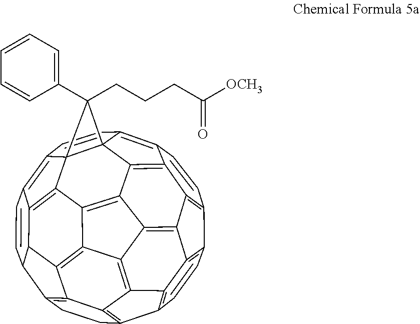 [SMILES: COC(=O)CCCC1(c2ccccc2)C23C4=C5C=CC6C7=c8c9c%10c(c%11c%12c%13c(ccc%14c%15ccc%16c(c8c8c%16c%15c(c%13%14)c%11c%108)CC7)=C(C=C4)C%1221)C3=C5C96]

Bis-PCBM may be represented by Chemical Formula 5b.

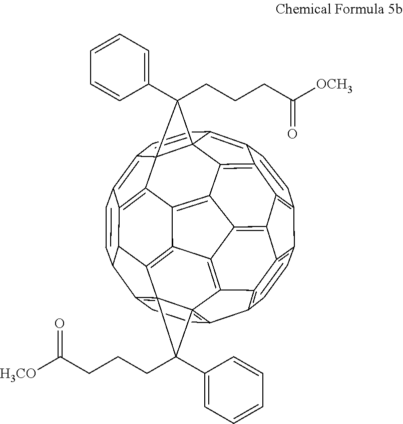

N2200 may be represented by Chemical Formula 5c.

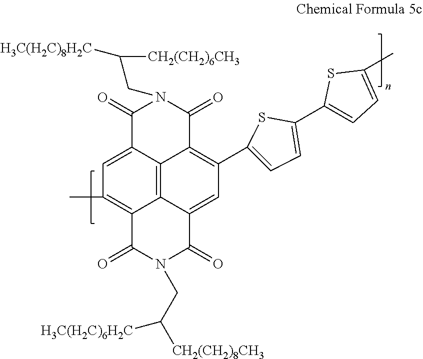

PDI may be represented by Chemical Formula 5d.

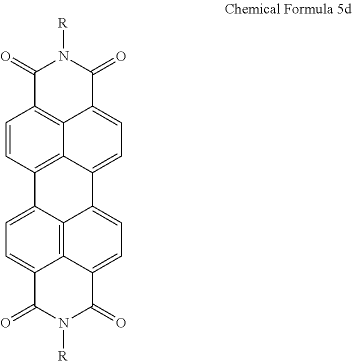

In Chemical Formula 5d, R may be a hydrogen, an alkyl group or an aryl group.

NDI may be represented by Chemical Formula 5e.

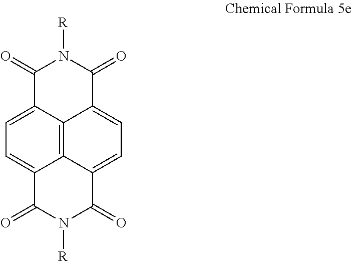

In Chemical Formula 5e, R may be a hydrogen, an alkyl group, or an aryl group. In an implementation, NDI may include a compound represented by Chemical Formula 5f (e.g., a compound represented by Chemical Formula 5e, in which each R is a dimethylamino-substituted ethyl group.

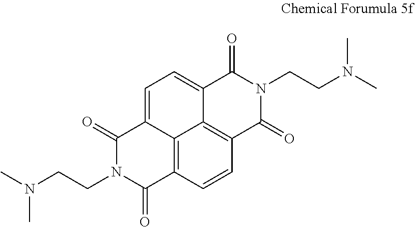

A light absorption spectrum of the light absorption material may have a peak at a wavelength greater than or equal to about 1 μm and less than about 1.5 μm. A light absorption spectrum of each of the light absorption material, the donor material, and the acceptor material individually may not have a peak at a wavelength greater than or equal to about 1.5 μm. However, a light absorption spectrum of the active layer 30 (e.g., in which all of the materials are combined or mixed) may have a peak at a wavelength greater than or equal to about 1.5 μm. This may be because the light absorption material and the acceptor material form a charge transfer complex (CTC), and a bandgap of the CTC may be less than a bandgap of the light absorption material and a bandgap of the acceptor material. Alternatively, this may be because the light absorption material and the donor material may form a CTC, and the bandgap of the CTC may be less than the bandgap of the light absorption material and a bandgap of the donor material. In general, the less a bandgap, the greater a wavelength of absorbed light.

In an implementation, the active layer 30 may include BDN as the light absorption material and may include PC70BM as the acceptor material. In this case, light absorption spectra of each of BDN and PC70BM may not individually have a peak at a wavelength greater than or equal to about 1.5 μm. In an implementation, the light absorption spectrum of BDN may have a peak at a wavelength greater than or equal to about 1 μm and less than about 1.5 μm. In an implementation, the light absorption spectrum of the entire active layer 30 may have a peak at a wavelength greater than or equal to about 1.5 μm. This is because BDN and PC70BM form a CTC, and the bandgap of the CTC may be less than the bandgap of the light absorption material and the bandgap of the acceptor material. In some embodiments, the active layer 30 may further include P3HT as the donor material.

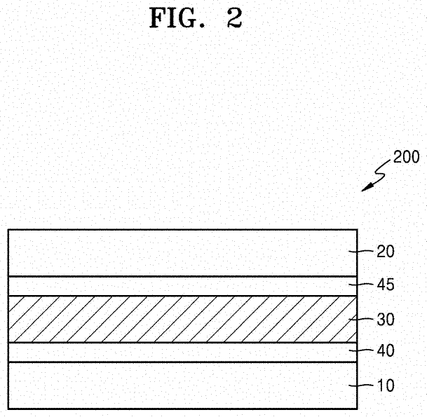

FIG. 2 is a cross-sectional view of an organic photoelectric conversion device 200 according to an embodiment.

Referring to FIG. 2, the organic photoelectric conversion device 200 may further include, e.g., a lower transport layer 40 between the lower electrode 10 and the active layer 30, and an upper transport layer 45 between the active layer 30 and the upper electrode 20, in addition to the organic photoelectric conversion device 100 shown in FIG. 1. In an implementation, the organic photoelectric conversion device 200 may include the lower electrode 10, the lower transport layer 40, the active layer 30, the upper transport layer 45, and the upper electrode 20 stacked in this stated order.

The lower transport layer 40 and the upper transport layer 45 may be a hole transport layer and an electron transport layer, respectively. In an implementation, the lower transport layer 40 and the upper transport layer 45 may be an electron transport layer and a hole transport layer, respectively. The electron transport layer may include, e.g., ZnO, TiO₂, polystyrene sulfonate (PSS), bathocuproine, or lithium fluoride (Lif). The hole transport layer may include, e.g., molybdenum oxide (MoO₃), nickel oxide (NiO), or poly(3,4-ethylenedioxythiophene) doped with PSS (PEDOT:PSS).

PSS may be represented by Chemical Formula 6a.

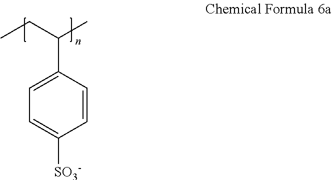

Bathocuproine may be represented by Chemical Formula 6b.

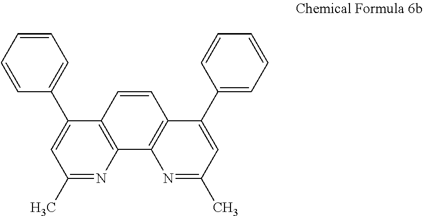 [SMILES: Cc1cc(-c2ccccc2)c2ccc3c(-c4ccccc4)cc(C)nc3c2n1]

PEDOT:PSS may be represented by Chemical Formula 6c.

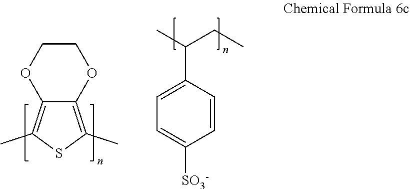

In an implementation, e.g., in which the active layer 30 includes BDN as the light absorption material and includes PC70BM as the acceptor material, external quantum efficiency (EQE) of the organic photoelectric conversion device 200 at −5 V for light of 1,300 nm may be about 0.03% or more. In an implementation, the active layer 30 may have a thickness of about 50 nm to about 100 nm.

In an implementation, e.g., in which the active layer 30 further includes P3HT as the donor material, the EQE of the organic photoelectric conversion device 200 at −5 V for light of 1,300 nm may be about 0.67% or more. In an implementation, by adding P3HT, the EQE of the organic photoelectric conversion device 200 may be improved. This may be because the crystallinity of the active layer 30 is improved by adding P3HT to the active layer 30. In an implementation, the active layer 30 may have a thickness of about 400 nm to about 600 nm.

The following Examples are provided in order to highlight characteristics of one or more embodiments, but it will be understood that the Examples are not to be construed as limiting the scope of the embodiments. Further, it will be understood that the embodiments are not limited to the particular details described in the Examples.

<Material>

BDN and PC70BM were used as materials of an active layer in a First Example, and BDN, PC70BM, and P3HT were used as materials of an active layer in a Second Example.

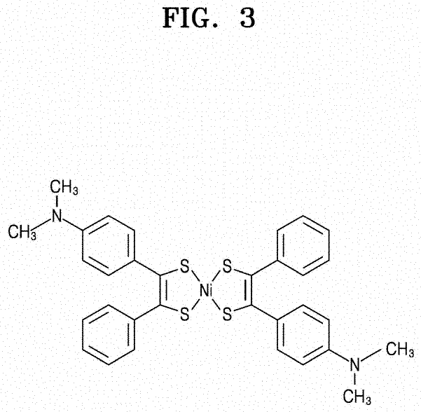

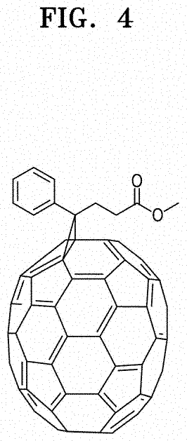

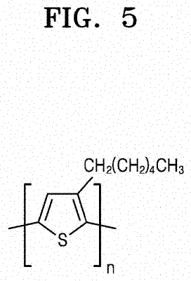

FIG. 3 is a chemical structure of BDN. FIG. 4 is a chemical structure of PC70BM. FIG. 5 is a chemical structure of P3HT.

<Light Absorption Spectrum of BDN>

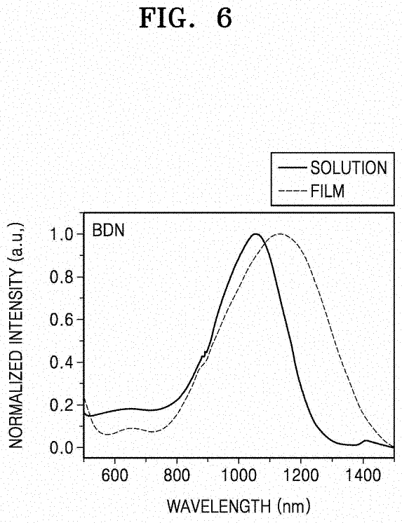

A light absorption spectrum of a BDN solution (10⁻⁵ M) in tetrahydrofuran (THF) and a light absorption spectrum of a BDN film were measured. FIG. 6 is a light absorption spectrum of BDN. The light absorption spectrum of the BDN solution is shown with a solid line in FIG. 6. The light absorption spectrum of the BDN film is shown with a dashed line in FIG. 6.

Referring to FIG. 6, both the BDN solution and the BDN film had strong absorbability in an infrared band. The light absorption spectrum of the BDN solution had a peak at a wavelength of about 1,060 nm. The light absorption spectrum of the BDN film had a peak at a wavelength of about 1,140 nm. Redshift of the peak wavelength of the light absorption spectrum of the BDN film with respect to the peak wavelength of the light absorption spectrum of the BDN solution resulted from improved crystallinity of a film state and an improved interaction between molecules. Therefore, for SWIR absorption, it may be significant to improve crystallinity of a film and an improved interaction between molecules.

<Energy Level of BDN>

An energy level of BDN was calculated by using a density functional theory

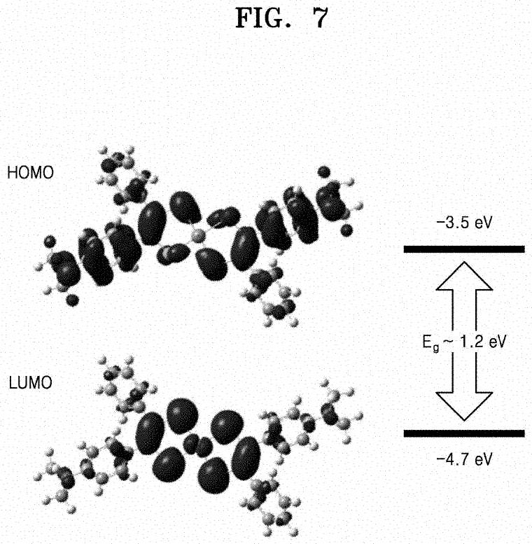

(DFT) simulation. FIG. 7 is an energy level calculation result of BDN. As a result of the simulation, BDN had a bandgap of about 1.2 eV. From this simulation result, BDN had a very narrow bandgap and is thus excellent for SWIR absorption. This may be because a wavelength of absorbed light increases as a bandgap is narrow.

<Light Absorption Spectrum of a Film in Which BDN and PC70BM are Mixed>

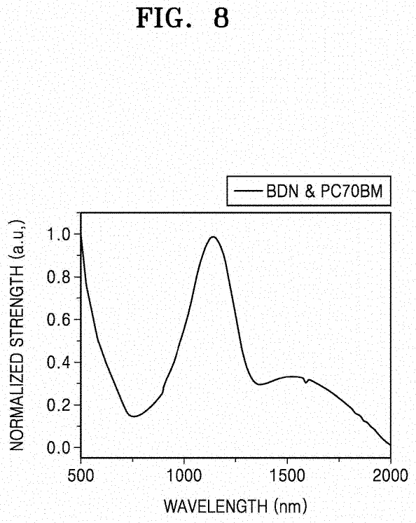

A light absorption spectrum of a film in which BDN and PC70BM are mixed was measured. FIG. 8 is a light absorption spectrum of the film in which BDN and PC70BM are mixed. Referring to FIG. 8, similarly to the light absorption spectrum of BDN, shown in FIG. 6, the light absorption spectrum of the BDN:PC70BM mixed film had a peak between about 1,100 nm and about 1,200 nm. However, unlike the light absorption spectrum of BDN, shown in FIG. 6, the BDN:PC70BM mixed film also had a peak at a wavelength of about 1,500 nm or more. This peak may be because BDN and PC70BM form a CTC, and the bandgap of the CTC is less than a bandgap of BDN and a bandgap of PC70BM.

<Manufacturing of First Example>

A glass substrate, on which ITO was grown to about 300 nm, was cleaned using toluene, acetone, or isopropyl alcohol (IPA). Thereafter, about 1 mL of a diethyl zinc solution was mixed with about 2 mL of THF, and then, the mixed solution was coated on the ITO by spin coating to form a ZnO film on the ITO. A thickness of the ZnO film was about 40 nm.

About 10 mg of BDN powder and about 10 mg of PC70BM powder were mixed at a 1:1 weight ratio with about 1 mL of chloroform. This mixture was stirred for two hours or more to produce a BDN:PC70BM solution. The ZnO film was coated with the BDN:PC70BM solution by spin coating to form a BDN:PC70BM mixed film. According to spin coating conditions, a thickness of the BDN:PC70BM mixed film may vary.

MoO₃ was formed with a thickness of about 4 nm on the BDN:PC70BM mixed film by thermal evaporation. Thereafter, an Au film was formed with a thickness of about 20 nm on the MoO₃ by thermal evaporation. The MoO₃ and the Au film were formed by using a shadow mask so as to expose the BDN:PC70BM mixed film therethrough.

The First Example formed as described above had a following structure:

Glass substrate/

ITO (300 nm)/ZnO (40 nm)/BDN:PC70BM/MoO₃ (4 nm)/Au (20 nm)

ITO was a lower electrode, ZnO was an electron transport layer, BDN:PC70BM was an active layer, MoO₃ was a hole transport layer, and Au was an upper electrode.

<Voltage-Current Measurement 1 of First Example>

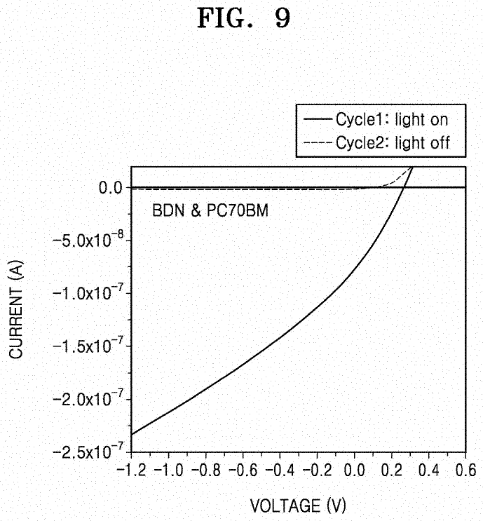

A voltage-current graph was measured when sunlight (6 mWcm⁻²) was irradiated on the First Example. FIG. 9 is a voltage-current graph of the First Example for sunlight. Referring to FIG. 9, a dashed line indicates a voltage-current graph when the sunlight was blocked, and a solid line indicates a voltage-current graph when the sunlight was irradiated. It may be seen that much photoelectric current was generated by the sunlight.

<Voltage-Current Measurement 2 and EQE Measurement of First Example>

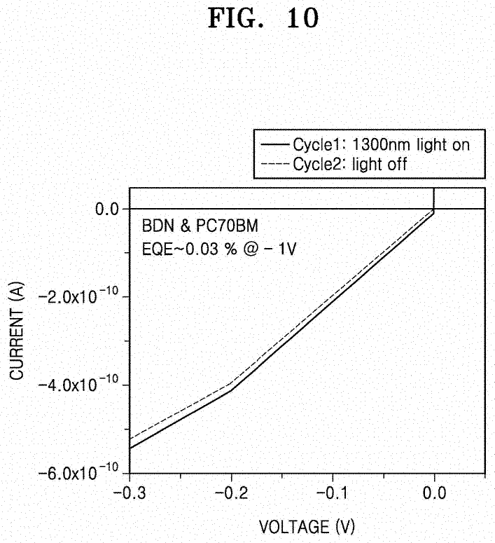

A voltage-current graph was measured when light of about 1,300 nm and about 5 μWcm⁻² was irradiated on the First Example. FIG. 10 is a voltage-current graph of the First Example for light of about 1,300 nm. Referring to FIG. 10, a dashed line indicates a voltage-current graph when the light of about 1,300 nm was turned off, and a solid line indicates a voltage-current graph when the light of about 1,300 nm was turned on. It may be seen that a little photoelectric current was generated by the light of about 1,300 nm. In addition, EQE of the First Example was calculated for the light of about 1,300 nm when a voltage of about −1 V is applied. As a result, the EQE of the First Example for the light of about 1,300 nm at about -1 V was about 0.03%.

<Time-Current Measurement and EQE Measurement of First Example>

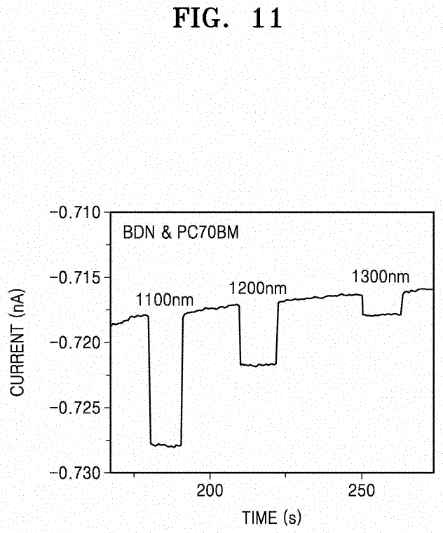

A time-current graph was measured in real-time while sequentially irradiating light of about 1,100 nm and about 80 μWcm⁻², light of about 1,200 nm and about 20 Wcm⁻², and light of about 1,300 nm and about 5 μWcm⁻² on the First Example. FIG. 11 is a time-current graph of the First Example. Referring to FIG. 11, it may be seen that a photoelectric current was generated for all of the light of about 1,100 nm, the light of about 1,200 nm, and the light of about 1,300 nm. In addition, EQE of the First Example was calculated when a voltage of about −5 V was applied. As a result, the EQE of the First Example for the light of about 1,300 nm at about −5 V was about 0.07%.

<Optical Microscopy Image and Atomic Force Microscopy (AFM) Image of Active Layer of First Example>

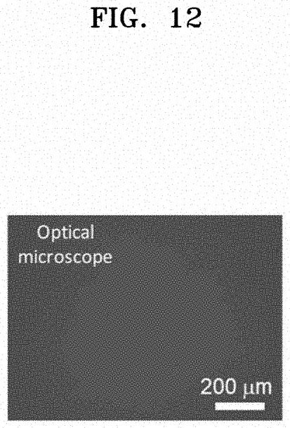

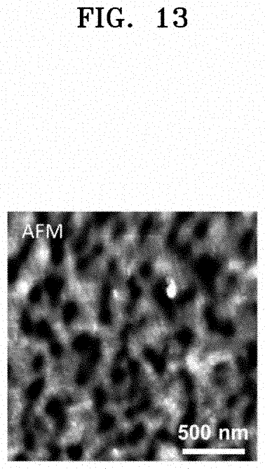

An optical microscopy image and an AFM image of an active layer of the first embodiment were captured. FIG. 12 is the optical microscopy image of the active layer of the First Example, and FIG. 13 is the AFM image of the active layer of the First Example. Referring to FIGS. 12 and 13, it may be seen that the active layer viewed through an optical microscope was uniformly formed, but in the AFM image, a plurality of shallow grooves having a size of about 10 nm were in the surface of the active layer.

<Cross-Sectional Profile of Active Layer of First Example>

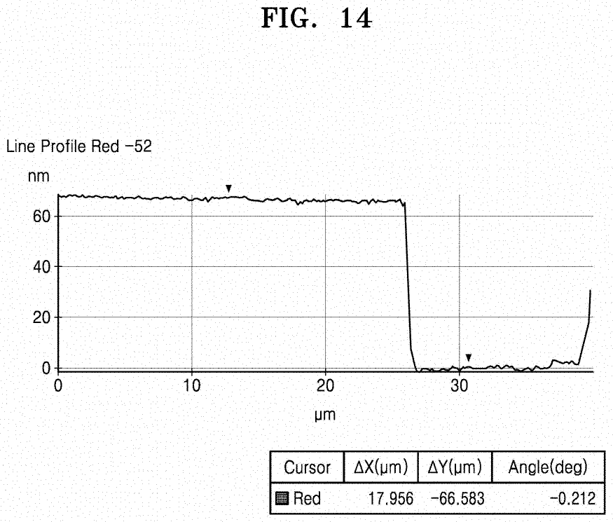

A cross-sectional profile of the active layer of the First Example was measured by using AFM. FIG. 14 is the cross-sectional profile of the active layer of the First Example, which was measured using AFM. Organic photoelectric conversion devices having BDN:PC70BM active layers of different thicknesses were prepared, and a cross-sectional profile of an active layer of an organic photoelectric conversion device exhibiting the highest EQE among the organic photoelectric conversion devices was measured. Referring to FIG. 14, a thickness of the active layer of the First Example exhibiting the highest EQE was about 70 nm. In an implementation, an optimal thickness of the active layer may be about 50 nm to about 100 nm.

<Manufacturing of Second Example>

A glass substrate, on which ITO was grown to about 300 nm, was cleaned by using toluene, acetone, or IPA. Thereafter, about 1 mL of a diethyl zinc solution was mixed with about 2 mL of THF, and then, the mixed solution was coated on the ITO by spin coating to form a ZnO film on the ITO. A thickness of the ZnO film was about 40 nm.

BDN powder, PC70BM powder, and P3HT powder were mixed at a 1:1:1 weight ratio with about 1 mL of chloroform. This mixture was stirred for two hours or more to produce a P3HT:BDN:PC70BM solution. The ZnO film was coated with the P3HT:BDN:PC70BM solution by spin coating to form a P3HT:BDN:PC70BM mixed film. According to spin coating conditions, a thickness of the P3HT:BDN:PC70BM mixed film may vary.

MoO₃ was formed with a thickness of about 4 nm on the P3HT:BDN:PC70BM mixed film by thermal evaporation. Thereafter, an Au film was formed with a thickness of about 20 nm on the MoO₃ by thermal evaporation. The MoO₃ and the Au film were formed by using a shadow mask so as to expose the P3HT:BDN:PC70BM mixed film therethrough.

The Second Example formed as described above had a following structure:

Glass substrate/ ITO (300 nm/ZnO (40 nm)/P3HT:BDN:PC70BM/MoO₃ (4 nm)/Au (20 nm)

ITO was a lower electrode, ZnO was an electron transport layer,

P3HT:BDN:PC70BM was an active layer, MoO₃ was a hole transport layer, and Au was an upper electrode.

<Time-Current Graph of Second Example>

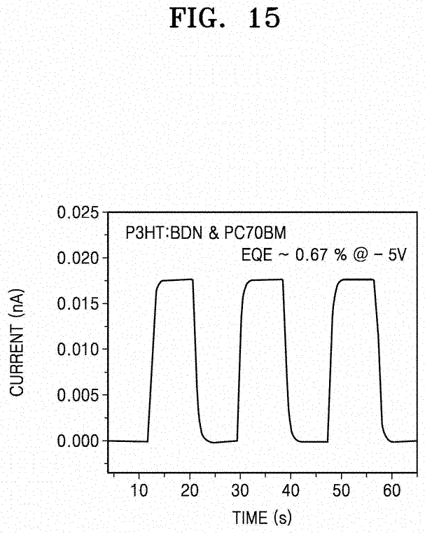

A time-current graph was measured in real-time while sequentially turning on and off light of about 1,300 nm and about 5 μWcm⁻² on the Second Example. FIG. 15 is a time-current graph of the Second Example. Referring to FIG. 15, it may be seen that a photoelectric current was generated by light of about 1,300 nm. In addition, EQE of the Second Example was calculated when a voltage of about −5 V was applied. As a result, the EQE of the Second Example at about −5 V was about 0.67%. The crystallinity of the active layer (P3HT:BDN:PC70BM) was improved by adding P3HT, and the Second Example had a higher EQE than the First Example.

<AFM Image of Active Layer of Second Example>

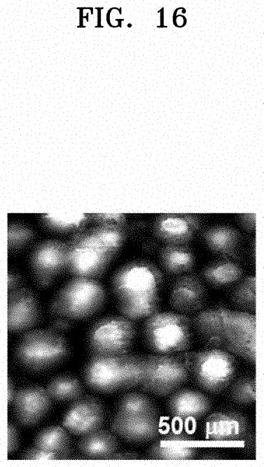

An AFM image of the active layer of the Second Example was captured. FIG. 16 is the AFM image of the active layer of the Second Example. Referring to FIG. 16, unlike the AFM image (see FIG. 13) of the active layer of the First Example, a film morphology including wide grains of about hundreds nm without grooves was observed. Addition of P3HT resulted in improving crystallinity of a film.

<Cross-Sectional Profile of Active Layer of Second Example>

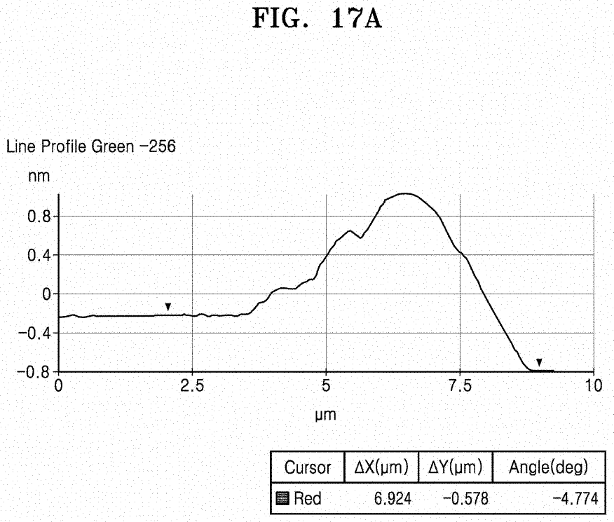

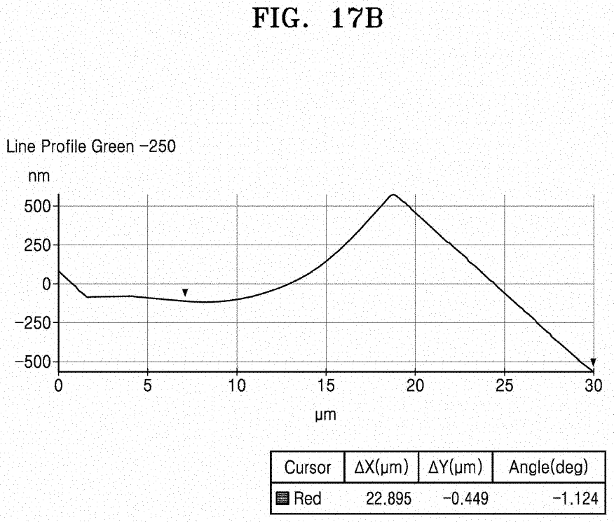

A cross-sectional profile of the active layer of the Second Example was measured by using AFM. FIGS. 17A and 17B are cross-sectional profiles of the active layer of the Second Example, which were measured using AFM. Organic photoelectric conversion devices having P3HT:BDN:PC70BM active layers of different thicknesses were prepared, and a P3HT:BDN:PC70BM film was manufactured in the same condition as that for forming an active layer of an organic photoelectric conversion device exhibiting the highest EQE among the organic photoelectric conversion devices. Referring to FIGS. 17A and 17B, a thickness of the active layer of the Second Example exhibiting the highest EQE was about 400 nm to about 600 nm. In an implementation, an optimal thickness of the active layer is about 400 nm to about 600 nm.

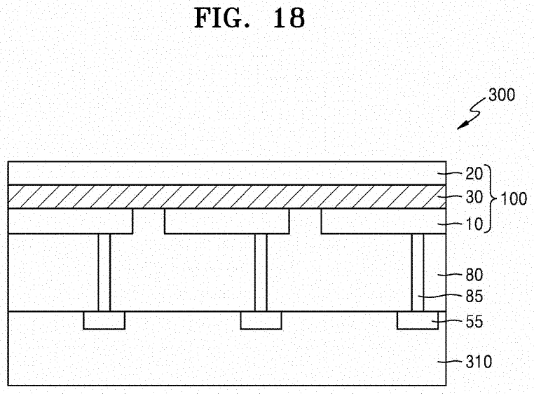

FIG. 18 is a cross-sectional view of an image sensor 300 according to an embodiment.

Referring to FIG. 18, the image sensor 300 may include a semiconductor substrate 310, a charge storage 55 in the semiconductor substrate 310, an insulating layer 80 on the semiconductor substrate 310, the organic photoelectric conversion device 100 on the insulating layer 80, and a wiring 85 connecting between the organic photoelectric conversion device 100 and the charge storage 55.

The semiconductor substrate 310 may include a semiconductor material, e.g., a group IV semiconductor material, a group III-V semiconductor material, or a group II-VI semiconductor material. The group IV semiconductor material may include, e.g., silicon (Si), germanium (Ge), or Si—Ge. The group III-V semiconductor material may include, e.g., gallium arsenide (GaAs), indium phosphide (InP), gallium phosphide (GaP), indium arsenide (InAs), indium antimonide (InSb), or indium gallium arsenide (InGaAs). The group II-VI semiconductor material may include, e.g., zinc telluride (ZnTe) or cadmium sulfide (CdS).

The charge storage 55 may be an impurity region in the semiconductor substrate 310. The charge storage 55 may also be referred as a floating diffusion region. The charge storage 55 may be connected to a transmit transistor on the semiconductor substrate 310. Photocharges generated by the organic photoelectric conversion device 100 may be transferred to the charge storage 55 through the wiring 85 and accumulated in the charge storage 55.

The insulating layer 80 may include a silicon oxide, a silicon nitride, or a low dielectric material. The low dielectric material may include, e.g., silicon carbide (SiC), silicon hydroxyl carbon (SiCOH), silicon oxycarbide (SiCO), silicon oxyfluoride (SiOF), flowable oxide (FOX), torene silazene (TOSZ), undoped silica glass (USG), borosilica glass (BSG), phosphosilica glass (PSG), borophosphosilica glass (BPSG), plasma enhanced tetra ethyl ortho silicate (PETEOS), fluoride silicate glass (FSG), carbon doped silicon oxide (CDO), xerogel, aerogel, amorphous fluorinated carbon, organo silicate glass (OSG), parylene, bis-benzocyclobutene (BCB), silicon low-k (SiLK), polyimide, a porous polymer material, or a combination thereof.

The organic photoelectric conversion device 100 may be similar to the organic photoelectric conversion device 100 described with reference to FIG. 1, but the lower electrode 10 may be divided into a plurality of parts respectively corresponding to a plurality of pixels. Light may be incident to the active layer 30 through the upper electrode 20, and the upper electrode 20 may be transparent to SWIR rays.

A plurality of wirings 85 may connect the plurality of parts divided from the lower electrode 10 to a plurality of charge storages 55, respectively. The wiring 85 may include, e.g., tungsten (W), Al, copper (Cu), Ag, Au, polysilicon, or the like.

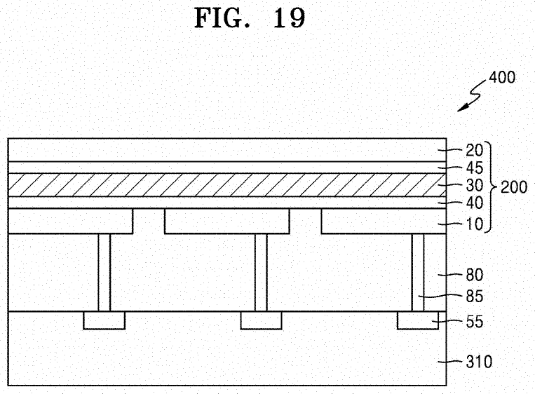

FIG. 19 is a cross-sectional view of an image sensor 400 according to an embodiment. Hereinafter, differences between the image sensor 300 shown in FIG. 18 and the image sensor 400 shown in FIG. 19 are described.

Referring to FIG. 19, the image sensor 400 may include the organic photoelectric conversion device 200 instead of the organic photoelectric conversion device 100 shown in FIG. 18. The organic photoelectric conversion device 200 may further include the lower transport layer 40 between the lower electrode 10 and the active layer 30, and the upper transport layer 45 between the active layer 30 and the upper electrode 20. The organic photoelectric conversion device 200 may be similar to the organic photoelectric conversion device 200 described with reference to FIG. 2, but the lower electrode 10 may be divided into a plurality of parts.

By way of summation and review, silicon cannot absorb SWIR rays, and thus, silicon may not be suitable for SWIR sensing. An image sensor including an indium gallium arsenide (InGaAs) SWIR photoelectric conversion device may be expensive.

One or more embodiments may provide an inexpensive SWIR photoelectric conversion device.

One or more embodiments may provide a short wave infrared (SWIR) organic photoelectric conversion device.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated.

Accordingly, it will be understood by those of skill in the art that various changes in form and details may be made without departing from the spirit and scope of the present invention as set forth in the following claims.

What is claimed is:

1. An organic photoelectric conversion device, comprising:
an upper electrode;
a lower electrode; and
an active layer between the upper electrode and the lower electrode,
wherein the active layer includes bis-(4-dimethylaminodithiobenzyl)-Ni(II) (BDN) and [6,6]-Phenyl-C71-butyric acid methyl ester (PC70BM).

2. The organic photoelectric conversion device as claimed in claim 1, wherein a light absorption spectrum of the active layer has a peak at a wavelength of 1.5 μm or more.

3. The organic photoelectric conversion device as claimed in claim 1, wherein the BDN and PC70BM form a charge transfer complex (CTC).

4. The organic photoelectric conversion device as claimed in claim 1, further comprising:
a lower transport layer between the active layer and the lower electrode; and
an upper transport layer between the active layer and the upper electrode,
wherein an external quantum efficiency (EQE) of the organic photoelectric conversion device at −5 V for light having a wavelength of about 1,300 nm is 0.07% or more.

5. The organic photoelectric conversion device as claimed in claim 1, wherein the active layer has a thickness of about 50 nm to about 100 nm.

6. The organic photoelectric conversion device as claimed in claim 1, wherein the active layer further includes poly-3-hexylthiophene (P3HT).

7. The organic photoelectric conversion device as claimed in claim 6, further comprising:
a lower transport layer between the active layer and the lower electrode; and
an upper transport layer between the active layer and the upper electrode,
wherein an external quantum efficiency (EQE) of the organic photoelectric conversion device at −5 V for light having a wavelength of about 1,300 nm is 0.67% or more.

8. The organic photoelectric conversion device as claimed in claim 6, wherein the active layer has a thickness of about 400 nm to about 600 nm.

9. An image sensor comprising the organic photoelectric conversion device as claimed in claim 1.

10. An organic photoelectric conversion device, comprising:
an upper electrode;
a lower electrode; and
an active layer between the upper electrode and the lower electrode,
wherein:
the active layer includes a first organic material and a second organic material,
the first organic material and the second organic material form a charge transfer complex, and
a light absorption spectrum of the charge transfer complex has a peak at a wavelength of 1.5 μm or more.

11. The organic photoelectric conversion device as claimed in claim 10, wherein:
a light absorption spectrum of the first organic material does not have a peak at a wavelength of 1.5 μm or more, and
a light absorption spectrum of each of the second organic material does not have a peak at a wavelength of 1.5 μm or more.

12. The organic photoelectric conversion device as claimed in claim 10, wherein a light absorption spectrum of the first organic material has a peak at a wavelength greater than or equal to 1.0 μm and less than 1.5 μm.

13. The organic photoelectric conversion device as claimed in claim 10, wherein:
the first organic material is represented by Chemical Formula 1a, Chemical Formula 1b, Chemical Formula 1c, or Chemical Formula 1d, 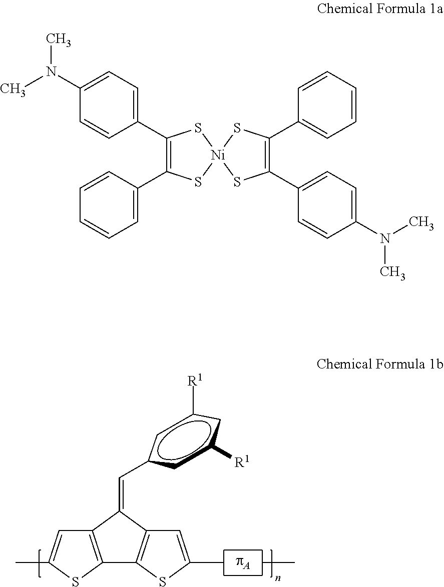
in Chemical Formula 1b,
each R¹ is independently an alkyl group,
n is a natural number between 1 and 10000 and
π_{A} is a group represented by Chemical Formula 2a, Chemical Formula 2b, or Chemical Formula 2c, 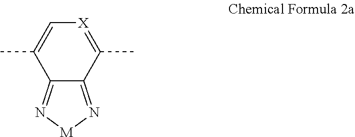
in Chemical Formula 2a,
M is sulfur (S) or selenium (Se), and
X is CH or nitrogen (N), 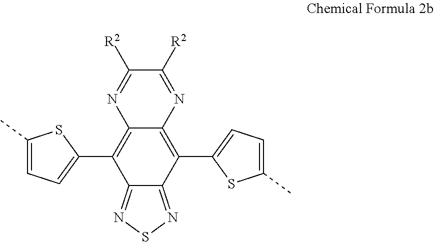
in Chemical Formula 2b, each R² is independently an alkyl group, 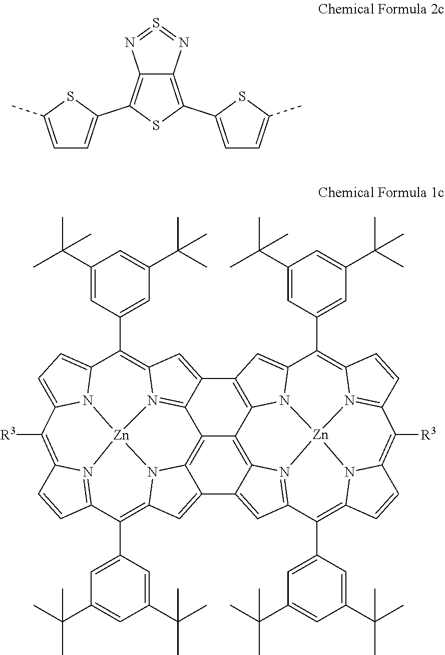
in Chemical Formula 1c, each R³ is independently a group represented by Chemical Formula 3a, Chemical Formula 3b, or Chemical Formula 3c,

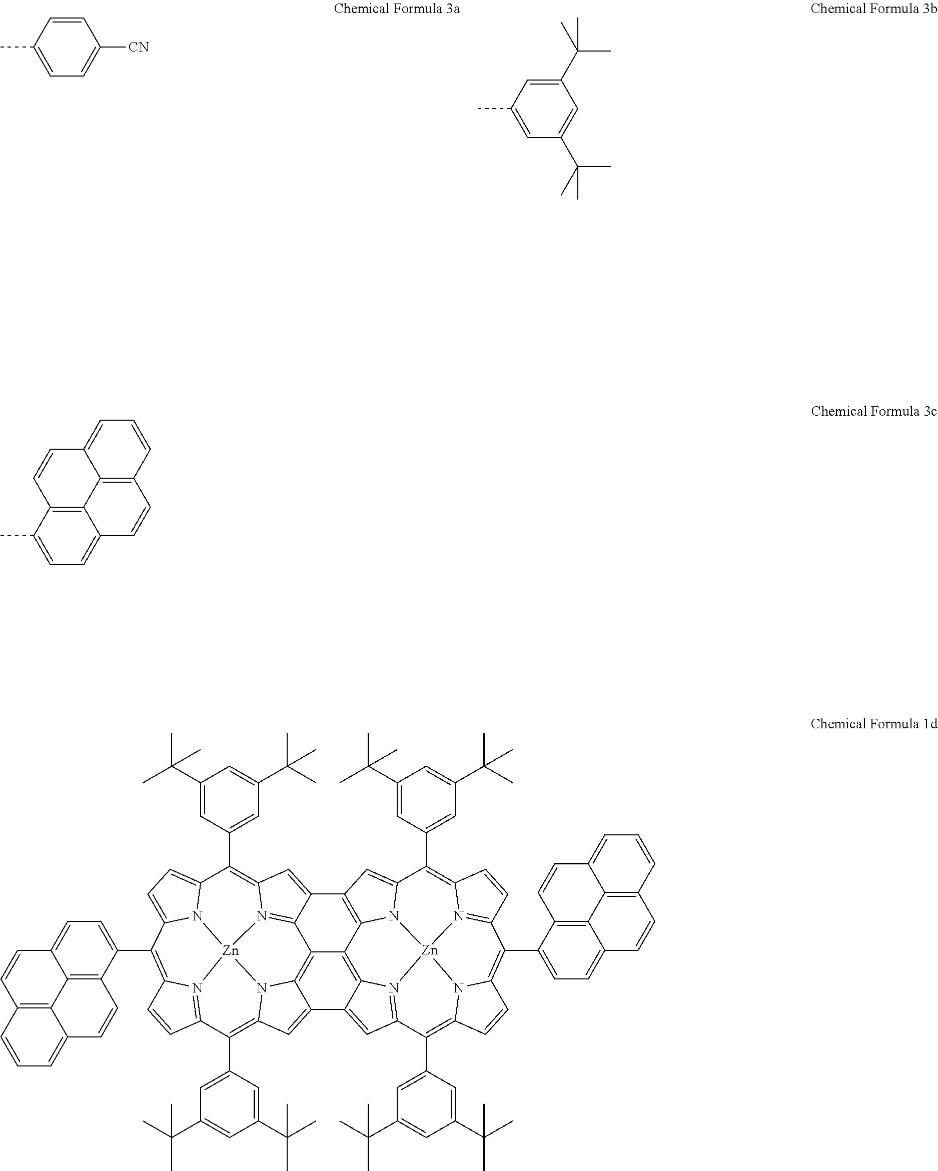

14. The organic photoelectric conversion device as claimed in claim 10, wherein the second organic material includes an acceptor.

15. The organic photoelectric conversion device as claimed in claim 10, wherein the second organic material includes [6,6]-phenyl-C71-butyric acid methyl ester (PC70BM), [6,6]-phenyl-C61-butyric acid methyl ester (PC₆₀BM), bis(1-[3-(methoxycarbonyl)propyl]-1-phenyl)[6,6]C62 (bis-PCBM), poly{[N,N-bis(2-octyldodecyl)-naphthalene-1,4,5,8-bis(dicarboximide)-2,6-diyl]-alt-5,5-(2,29-bisthiophene)} (N2200), perylene diimide (PDI), or naphthalene diimide (NDI).

16. The organic photoelectric conversion device as claimed in claim 10, wherein:
the active layer further includes a third organic material, and
the third organic material includes a donor.

17. The organic photoelectric conversion device as claimed in claim 10, wherein:
the active layer further includes a third organic material, and
the third organic material includes poly-3-hexylthiophene (P3HT), poly[2-methoxy-5-(3,7-dimethyoctyoxyl)-1,4-phenylenevinylene] (MDMO-PPV), poly[[4,8-bis[(2-ethylhexyl)oxy]benzo[1,2-b:4,5-b′]dithiophene-2,6-diyl][3-fluoro-2-[(2-ethylhexyl)carbonyl]thieno[3,4-b]thiophenediyl]] (PTB7), poly[2,6-(4,4-bis-(2-ethylhexyl)-4H-cyclopenta [2,1-b;3,4-b′]dithiophene)-alt-4,7(2,1,3-benzothiadiazole)] (PCPDTBT), poly[N-9′-heptadecanyl-2,7-carbazole-alt-5,5-(4′,7′-di-2-thienyl-2′,1′,3′-benzothiadiazole)] (PCDTBT), or poly{2,2′-(2,5-bis(2-octyldodecyl)-3,6-dioxo-2,3,5,6-tetrahydropyrrolo[3,4-c]pyrrole-1,4-diyl)dithieno[3,2-b]thiophene-5,5′-diyl-alt-thiophen-2,5-diyl} (DPPTT-T).

18. The organic photoelectric conversion device as claimed in claim 10, wherein:
the active layer further includes a third organic material, and
a light absorption spectrum of the third organic material does not have a peak at a wavelength of 1.5 μm or more.

19. An image sensor comprising the organic photoelectric conversion device as claimed in claim 10.

20. An image sensor, comprising:
a semiconductor substrate;
a charge storage in the semiconductor substrate;
an insulating layer on the semiconductor substrate;
an organic photoelectric conversion device on the insulating layer; and
a wiring connecting between the organic photoelectric conversion device and the charge storage,
wherein:
the organic photoelectric conversion device includes:
a lower electrode connected to the wiring;
an active layer on the lower electrode; and
an upper electrode on the active layer,
the active layer includes a first organic material and a second organic material,
the first organic material and the second organic material form a charge transfer complex, and
a light absorption spectrum of the charge transfer complex has a peak at a wavelength of 1.5 μm or more.
